(19) United States
(12) Patent Application Publication
(10) Pub. No.: US 2026/0318953 A1
(43) Pub. Date: Oct. 15, 2026

(54) DEVICE FOR ELECTRICALLY TESTING SEMICONDUCTOR COMPONENTS

(71) Applicant: Rainer GAGGL, Drobollach (AT)

(72) Inventors: Rainer GAGGL, Drobollach (AT); Sebastian SALBRECHTER, Moosburg (AT)

(21) Appl. No.: 19/120,097

(22) PCT Filed: Apr. 17, 2024
(86) PCT No.: PCT/EP2024/060363

§ 371 Date: Apr. 10, 2025

(30) Foreign Application Priority Data
Apr. 18, 2023 (AT) A 50281/2023

(51) Int. Cl. G01R 1/073; G01R 1/067; G01R 31/28

(52) U.S. Cl. CPC G01R 1/07371; G01R 1/0675; G01R 1/07314; G01R 31/2886

(57) ABSTRACT

This relates to a device for electrically testing semiconductor components, such as wafers or chips, including a test head with a plurality of test needles, in particular a test head in the form of a vertical probe card, wherein the test needles are movably guided in holes of a guide plate and protrude beyond the guide plate in the direction of the semiconductor component to be tested. A protective plate is provided on the guide plate and the test needle ends which protrude beyond the guide plate and have the tips pass through the protective plate.

The invention relates to a device for electrically testing semiconductor components with the features of the preamble of claim 1.

These devices contain test heads in their probe cards, which can be designed as so-called vertical probe cards. A vertical probe card is known, for example, from AT 14 209A1 . The test needles are accommodated in guide plates and are guided in holes so that they can move relative to the lower guide plate adjacent to the semiconductor component (e.g. a chip). Vertical probe cards have a plurality of test needles, all of which pass through holes in the lower guide plate (ceramic plate) and are guided in these holes so that they can be moved relative to the lower guide plate and when placed on the power semiconductor chip to be tested, they elastically deform (bend) above the lower guide plate so that the tips of the test needles are resiliently flexible.

When testing microchips (“power chips”), very high currents, currently up to 3000 amperes, are sometimes used.

In order to ensure that these currents can be introduced into the chip without overloading the contact points to the chip to be tested and with the most homogeneous current distribution possible, a very large number of test needles are used, which are distributed almost evenly over the surface of the chip to be tested. With a nominal current of 1 ampere per test needle, this results in a vertical probe card with approximately 3000 test needles.

If there is a defect in the chip to be tested (a so-called “hot spot”), very high power losses occur at certain points on the surface of the chip. This can cause the metallization of the chip to melt and spray or evaporate explosively, depending on the material of the metallization. This can lead to metal deposits forming on the test needles of the vertical probe card and on the lower guide plate (ceramic plate) of the test head, in which the test needles are guided in a slidable manner. If there is a defect in the chip to be tested (a so-called “hot spot”), high power losses occur at the defect in the chip during electrical testing. Depending on the energy input when testing the chip and depending on the material of the metallization in the chip, this can lead to the metallization material melting and explosively splashing or explosively evaporating. This can lead to metal deposits forming on the ends (tips) of the test needles that protrude beyond the lower guide plate and/or on the lower guide plate (ceramic plate) of the test head, in which the test needles are guided in a slidable manner.

If metal is deposited on the tips of the test needles protruding beyond the lower guide plate and/or on the lower guide plate, the mobility of the test needles relative to the guide plate is impaired or prevented.

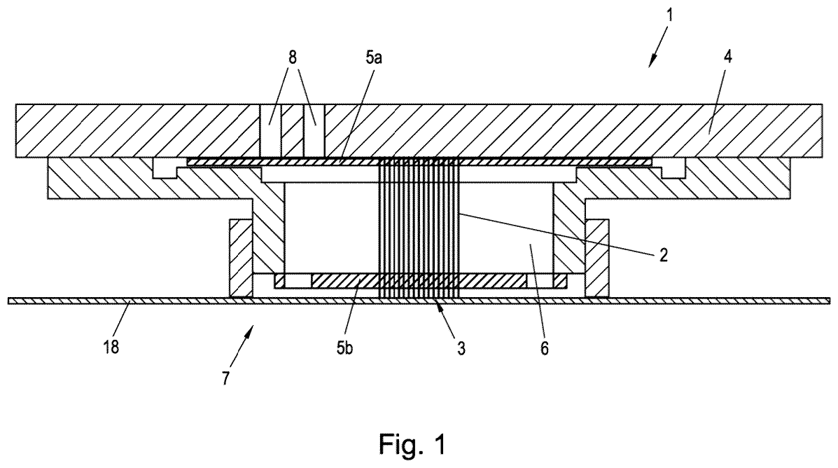

JP 2000-241454 A describes a device for testing semiconductor components, wherein a protective plate is provided on a guide plate and the ends of the test needles projecting beyond the guide plate penetrate through the protective plate (see FIG. 1). The protective plate is fastened to the surface of the guide plate facing the semiconductor component to be tested.

CN 217181007 U and CN 218180937 U describe devices for electrical testing of semiconductor components.

The object of the invention is to ensure the mobility of test needles even if metal of the chip evaporates and/or splashes during testing due to a defect in the chip.

The object is achieved with a device having the features of claim 1.

Preferred and advantageous developments of the device according to the invention are the subject of the dependent claims.

The invention proposes to attach (for example, glue) a cover in the form of a protective plate to the underside-the side facing the semiconductor component (chip) to be tested—of the lower guide plate, wherein the test needles engage through holes in the protective plate in a manner that is movable relative to the protective plate. The protective plate shields (like an umbrella) from splashes of liquid metal and/or vaporized metal from the probe card, in particular from the lower guide plate.

A protective plate, for example in the form of a plastic plate, has the advantage that the mobility of the needles is ensured even if the needles carry metal deposits from the (power) chip. In addition, a protective plate made of plastic has the advantage that metal adheres poorly or not at all to the plastic, so that the test needles remain mobile.

If the protective plate is made of (relatively) soft material, the test needles remain movable relative to the guide plate, even if metal has deposited on the tips of the needles. Metal deposited on the test needles may cause the holes in the protective plate to widen, allowing the test needles to remain movable relative to the lower guide plate (and the protective plate).

The holes in the protective plate through which the test needles pass can be dimensioned such that there is clearance between the holes and the test needles, so that the mobility of the tips of the test needles relative to the protective plate is ensured, even if metal is deposited in the region of the holes and/or on the tips of the test needles.

The protective plate (plastic plate) is preferably connected to the probe card's test head by gluing. A measure can be taken to prevent adhesive from being sucked into the center of the protective plate by capillary action and “sticking” the test needles. This measure may include openings, for example slot-shaped openings, arranged around the center, i.e. around the region where the test needles of the test head pass through the protective plate. Such openings interrupt the capillary effect so that no adhesive between the guide plate and the protective plate gets into the region of the test needles.

Since the exact guidance of the tips of the test needles is ensured by the lower guide plate of the test head, the holes in the protective plate can be dimensioned in such a way that the tips of the test needles are accommodated in the holes of the protective plate with some clearance. A clearance between the test needles and the holes in the protective plate also has the advantage that the risk of metal deposited in the region of the holes on the protective plate impairing the mobility of the tips of the test needles is prevented or at least reduced.

Further details, advantages and features of the invention will be apparent from the following description of exemplary embodiments based on the drawing. In the drawing:

FIG. 1 shows a vertical probe card, for example known from AT 14 209U1,

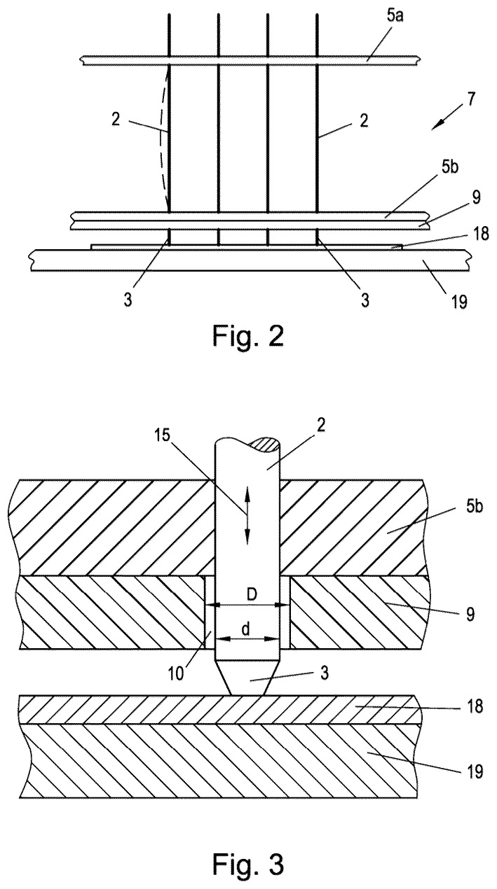

FIG. 2 is a basic representation of a probe card test head with protective plate,

FIG. 3 is a detail of the test head of FIG. 2 in enlarged view and in section and

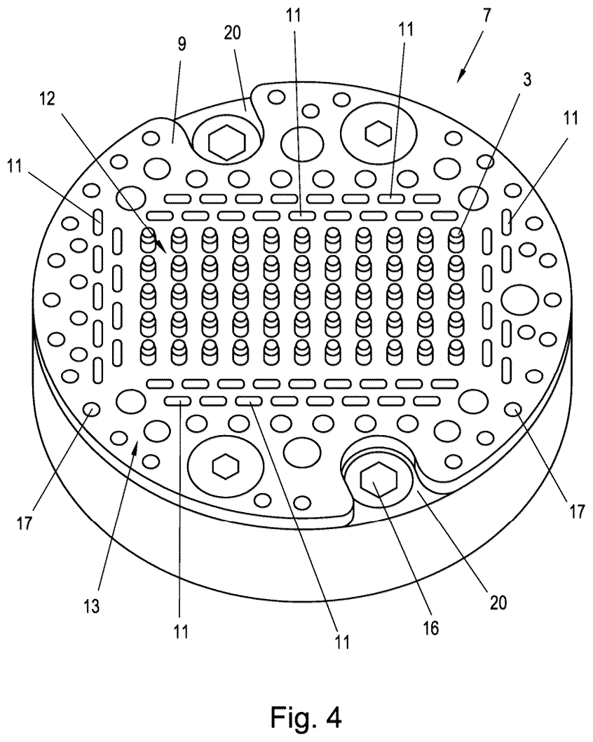

FIG. 4 is a view from below of a probe card test head with protective plate.

A test head 7 of a vertical probe card 1 comprises a plurality of, for example, angled, test needles 2. The test needles 2 and their tips 3 are shown symbolically in FIGS. 1 and 4. In practice, for example, up to 3000 or more test needles 2 are provided. In the test head 7, guides comprising an upper guide plate 5a and a lower guide plate 5b are provided. The tips 3 of the test needles 2 protrude beyond the lower guide plate 5b and are movably guided in holes in the lower guide plate 5b. The test head 7 has a pressure chamber 6 which can be supplied with compressed gas via lines 8. In the device according to the invention, a pressure chamber 6 in the test head 7 is not necessarily provided.

When the vertical probe card 1 with the test head 7 is placed on a semiconductor component to be tested, in the example shown a wafer 18 which is held on a holder (chuck) 19, the tips 3 of the test needles 2 move upwards relative to the lower guide plate 5b (double arrow 15 in FIG. 3), wherein the regions of the test needles 2 lying between the guide plates 5a and 5b bend (bend out) under elastic deformation, as is indicated for a test needle in FIG. 2 by a dashed line (idealized!).

A protective plate 9 (see FIGS. 2 and 3) is attached to the test head 7 of the vertical probe card 1 on the outer side (underside) of the lower guide plate 5b facing the wafer 18. Holes 10 are provided in the protective plate 9 for the ends of the test needles 2 which protrude downwards beyond the lower guide plate 5b and the protective plate 9 and carry the tips 3. The test needles 2 may have a certain clearance relative to the holes 10 in the protective plate 9.

The clearance arises because the diameter “D” of the holes 10 in the protective plate 9 is larger than the diameter “d” of the test needles 2. For example, the diameter “D” is in the order of 63 um and the diameter “d” is in the order of 80 μm.

By allowing a clearance of the test needles 2 in the holes 10 of the protective plate 9, it is also ensured that the mobility of the test needles 2, which are accommodated in the holes of the lower guide plate 5b (made of ceramic material) with a sliding guide (linear sliding bearing), is not hindered by the protective plate 9. This also applies if the axes of the holes 10 in the protective plate 9 are offset from the axes of the holes in the lower guide plate 5b.

The clearance between the test needles 2 and the holes 10 in the protective plate can be 10 μm to 20 μm, and in particular 17 μm.

The protective plate 9 consists, for example, of an electrically insulating and preferably elastically deformable plastic material, for example of a polyimide.

The protective plate 9 prevents metal components that are ejected (splashed) from the wafer 18 due to defects in the wafer 18 during testing of the wafer 18 by explosive melting and/or evaporation of metal from the metallization of the wafer 18 from accumulating on the test needles 2 in the region of the lower guide plate 5b. Thus, movements of the test needles 2 relative to the lower guide plate 5b are not restricted or prevented. If there is clearance between the holes 10 in the protective plate 9 and the test needles 2, the test needles 2 are still movable if metal that has been splashed from the wafer 18 or chip by explosive melting and/or evaporation of metal of the metallization has accumulated in the region of the holes 10 in the protective plate 9 and/or on the test needles 2.

As shown in FIG. 4, the protective plate 9 is designed such that it covers the entire underside of the test head 7 facing the semiconductor component to be tested (wafer 18) and thus also the underside of the lower guide plate 5b of the vertical probe card 1.

For fastening the protective plate 9 to the housing of the test head 7 of the vertical probe card 1, an adhesive technique is preferably considered.

In the protective plate 9, a plurality of holes 17, for example circular holes, are provided in an region 13 which lies outside the region 12 in which the holes 10 for the test needles 2 are provided. (Flowable) adhesive can be applied through the holes 17. Adhesive is distributed by capillary action between the protective plate 9 and the lower guide plate 5b.

In order to prevent adhesive from being sucked by capillary action from the region 13 outside the region 12 of the lower guide plate 5b and the protective plate 9, in which the test needles 2 protrude with their tips 3 through the protective plate 9, into the region 12 with the test needles 2, openings, which have the shape of slot-shaped holes 11, for example, are provided around the region 12. In the embodiment of FIG. 4, the holes 11 are arranged in two rows (“double row”). The slot-shaped holes 11 ensure that no adhesive is sucked from the region 13 outside the region 12 in which the test needles 2 are provided into the region 12 with the test needles 2 by capillary action and the movement of the test needles 2 relative to the lower guide plate 5b is hindered or prevented by sticking (adhering) the test needles 2 to the protective plate 9 and/or to the lower guide plate 5b.

In the protective plate 9, recesses 20 are provided which are open to the outside and through which access to the mounting screws 16 of the test body 7 is possible.

The guide plates 5a and 5b are made of electrically insulating material, in particular ceramic, so that the test needles 2 are electrically insulated from each other.

In summary, an exemplary embodiment of the invention can be described as follows:

A device for testing wafers 18 or chips has a test head 7 in the form of a vertical probe card 1, the test needles of which are guided in a ceramic guide plate 5b with a sliding guide. A protective plate 9 is glued to the underside of the guide plate 5b facing the wafer 18 or chip to be tested. The test needles 2 protrude with clearance through holes 10 in the protective plate 9. Holes 17 are provided in the protective plate 9 through which adhesive can be introduced between the protective plate 9 and the lower guide plate 5b. Slot-shaped holes 11 are provided in the protective plate 9 around the region 12 in which the holes 10 for the test needles 2 are located. The holes 11 prevent adhesive from being sucked into the region 12 by interrupting the capillary action occurring between the protective plate 9 and the lower guide plate 5b.

1. A device for electrically testing semiconductor components, such as wafers or chips, the device comprising:
a test head;
a plurality of test needles extending from the test head;
a guide plate arranged so that the test needles are movably guided in holes of the guide plate and protrude beyond the guide plate in a direction of the semiconductor component to be tested; and
a protective plate is provided on the guide plate such that tips of the test needles that protrude beyond the guide plate to make contact with the semiconductor component pass through the protective plate.

2. The device according to claim 1, wherein the protective plate is fastened to a surface of the guide plate facing the semiconductor component to be tested.

3. The device according to claim 1, wherein the protective plate is fastened to the guide plate outside a region in which the test needles are provided.

4. The device according to claim 2, further comprising an adhesive securing the protective plate to the guide plate.

5. The device according to claim 3, further comprising holes in the protective plate around the region in which the test needles are provided.

6. The device according to claim 5, wherein the holes are slot-shaped.

7. The device according to claim 5, wherein the holes are arranged in two rows parallel to one another and surrounding the region in which the test needles are provided.

8. The device according to claim 1, wherein the protective plate comprises holes that are provided in region of an outer edge of the protective plate.

9. The device according to claim 8, wherein the holes are circular.

10. The device according to claim 8, wherein the holes are provided in a region of the protective plate outside a region in which the test needles are provided.

11. The device according to claim 1, wherein the protective plate comprises electrically insulating material.

12. The device according to claim 1, wherein the protective plate comprises elastic material.

13. The device according to claim 1, wherein the test needles are received in holes in the protective plate.

14. The device according to claim 13, wherein the holes are configured so that the test needles pass through the holes with a clearance.

15. The device according to claim 1, wherein the protective plate extends over an entire surface of the test head facing the semiconductor component to be tested.

16. The device of claim 10, wherein the holes are slot-shaped.

17. The device of claim 1, wherein the test head is a vertical probe card.
